(19) United States
(12) Patent Application Publication
(10) Pub. No.: US 2002/0054813 A1
(43) Pub. Date: May 9, 2002

(54) Apparatus for handling integrated circuits and trays for integrated circuits

(76) Inventors: Vladimir Nikolayevich Davidov, Saint Petersburg (RU); Sergey Removich Belousov, Saint Petersburg (RU); Sergey Mikhailovich Pyko, St.Petersburg (RU)

Correspondence Address: DAVIDOV Vladimir Nikolalyevich, Office 501, 58, Moika Embankment, St.Petersburg, 190000, RU

(21) Appl. No.: 09/986,523

(22) Filed: Nov. 2, 2001

Related U.S. Application Data
(63) Continuation-in-part of application No. PCT/RU00/00136, filed on Mar. 6, 2000.

(51) Int. Cl. B65G 65/00; B65G 57/00; G01R 31/26

(52) U.S. Cl. 414/788.1; 414/403; 324/765

(57) ABSTRACT

A handling assembly for handling integrated circuits and trays for receiving these integrated circuits, the handling assembly comprising at least one integrated circuit manipulator having a holder pivoted on a fixed axis of rotation; the holder having a plurality of grippers arranged substantially in the plane passing through said axis of rotation, the holder being adapted to rotate said plurality of grippers at least to a first and second angular positions, a tray transporter adapted to move a tray into an operational position in which at least one of the integrated circuits in the tray is engageable by at least one of the grippers rotated to the first angular position, and an integrated circuit receiving/releasing means engageable by at least one of the grippers rotated to the second angular position.

An integrated circuit handling apparatus used in combination with a testing apparatus and applicable for handling integrated circuits and trays for receiving thereof. The said handling assemblies are used in the handling apparatus for performing the three following operations: receiving a tray of integrated circuits to be tested and transporting the tray to an operational position where the integrated circuits are transferred from the tray to test sockets of the testing apparatus and back to the tray, separating the tested integrated circuits by quality according to their test results, and placing the tested integrated circuits in trays for discharging.

### BACKGROUND OF THE INVENTION

1. Technical Field

The present invention relates generally to an integrated circuit handling apparatus used in combination with a testing apparatus and applicable for handling integrated circuits and trays for receiving thereof. More specifically, the invention relates to an integrated circuit handling apparatus for perfoming the three following operations:

receiving a tray of integrated circuits to be tested and transporting the tray to an operational position where the integrated circuits are transferred from the tray to test sockets of the testing apparatus and back to the tray,

separating the tested integrated circuits by quality according to their test results, and

placing the tested integrated circuits in trays for discharging.

Also, the invention relates to a multi-purpose handling assembly for handling integrated circuits and trays for receiving these integrated circuits, which assembly can perform either of the above three operations.

2. Description of Prior Art

In the semiconductor industry the integrated circuits are tested after each step of fabrication by applying test signals of a predetermined pattern. Many testing systems comprise a handling apparatus for automatically receiving the tested integrated circuits, bringing them into electrical contact with sockets of the test head, separating by quality and discharging.

In the following disclosure integrated circuits will also be referred to as IC. Further, “integrated circuit handling apparatus” will generally be equivalent to “integrated circuit handler” or “IC handler”.

In many cases the speed of operation of a handler limits the speed of testing. Whereas a testing apparatus can test devices at a high speed, the speed of loading, contacting, sorting and unloading devices often limits the overall throughput of the testing apparatus, due to insufficient capacity of loading and unloading means, testing manipulators and sorting devices.

Known are pick-and-place handlers capable of picking up ICs and transporting them to a desired location by means of X-Y direction transport means. However, handlers of this type require a large amount of expensive positioning equipment and thus usually are expensive. Further, they are low in throughputs because the ICs are processed successively, one by one, each handled IC passing through many time-taking elementary movements.

In many known handlers of the “gravity feed” type, the integrated circuits are caused to slide within the apparatus along inclined guideways under the influence of gravity, by their own weight (see, for example, U.S. Pat. No. 4,781,494). With a handler of this type, the need for transport mechanisms is reduced or eliminated, allowing to simplify the handler construction while obtaining a high throughput, especially when a testing apparatus used with the system can test a number of ICs simultaneously. However, it has been difficult to provide a loading and unloading means of a sufficient capacity and adequate speed.

Also, a bottleneck of the present handling technologies is the sorting operation usually involving transportation of tested ICs along narrow paths that often may cause stoppage and prevents from achieving high speed. Slow transportation and imperfect switching mechanisms prevent from separating tested ICs by quality into as many categories as required.

Customer trays usually interact with handlers as follows. First, a customer tray full of untested ICs is removed from its respective magazine and placed in a position so that the ICs are accessible and can be transferred to a test tray and undergo subsequent testing. This phase of the IC handling is typically referred to as “loading.” Then, the ICs are transported through the handler, tested and sorted. Further, empty customer trays must be placed in position with respect to the handler to receive tested ICs sorted into several test categories. Each customer tray is further received in an appropriate magazine, again according to the test categories. This phase of the operation is typically referred to as “unloading.” A great many of load/unload operations slow down the ICs processing and cause reductions in throughput.

Still another problem of the present handling technologies is the use of batch operating testing apparatus devices which require frequent reloading. Typically, during reloading, the testing apparatus is out of work that causes decrease in IC throughput. One way of increasing the throughput of handlers of the above type is to increase the number of testing positions for testing a plurality of ICs simultaneously. It has become a test technology standard to place a number of electronic devices to be tested in a tray and position them so as to be engaged by a test head plate having a number of corresponding test contactors, as in horizontal handlers manufactured by Advantest Corporation and described, e.g., in U.S. Pat. No. 5,307,011 or 5,313,156. However, the use of a tray having a number of ICs arranged therein requires precise vertical and horizontal alignment with a test fixture that is a highly expensive operation.

Thus, in test handling equipment of the prior art, a number of disadvantages have become apparent. First, there is a need for extensive handling of individual ICs. That is, the ICs to be tested shall be removed from a customer tray and placed in an appropriate position prior to testing. It is also necessary, following the test, to sort the tested ICs according to the test results and place them into customer trays for return shipping to the customer or other appropriate destination. This technique involves a number of excess operations which increase the time of the overall processing.

If delays occur on either stage, the throughput and thus the productivity of the handler will be decreased. In particular, the unload phase is likely to cause delays because of a need to sort the tested ICs, whereas sorting is one of the most complicated operations involving a compound motion along divaricate paths, thus incurring increased handling time.

Accordingly, there is a serious need in the integrated circuit industry for an automatic test handler which can overcome the problems and disadvantages described above in connection with processing ICs received in customer trays and provide both operator-friendly and high-speed testing with high sorting capabilities.

### BRIEF SUMMARY OF THE INVENTION

It is an object of the present invention to solve the above-described problems at least partially by providing an integrated circuit handling apparatus capable of perfoming, with a very high throughput, the three following operations:

receiving a tray of integrated circuits to be tested and transporting the tray to an operational position where the integrated circuits are transferred from the tray to test sockets of the testing apparatus and back to the tray,

separating the tested integrated circuits by quality according to their test results, and

placing the tested integrated circuits in trays for discharging.

Another object of this invention is to provide a multi-purpose handling assembly for handling integrated circuits and trays for receiving these integrated circuits, which assembly can perform either of the above three operations.

Still another object of this invention is to provide an integrated circuit handling apparatus which does not take much space and which is relatively cheap, easily-maintained, reliable and convenient in operation.

Still another object of this invention is to provide an integrated circuit handling apparatus built up of unified interchangeable modules.

In accordance with one aspect of the present invention, claimed is a handling assembly for handling integrated circuits and trays for receiving these integrated circuits, the handling assembly comprising at least one integrated circuit manipulator having a holder pivoted on a fixed axis of rotation; the holder having a plurality of grippers arranged substantially in the plane passing through said axis of rotation, the holder being adapted to rotate said plurality of grippers at least to a first and second angular positions; a tray transporter adapted to move a tray into an operational position in which at least one of the integrated circuits in the tray is engageable by one of the grippers rotated to the first angular position, and an integrated circuit receiving/releasing means engageable by at least one of the grippers rotated to the second angular position.

The above handling assembly can further comprise at least one tray magazine for stacking the trays, the magazine being provided with a mechanism for moving the trays between the stack and the tray transporter.

Said tray magazine can be arranged upstream the operational position to function as an input tray magazine. In this case the handling assembly can further comprise another tray magazine arranged downstream the operational position to function as an output tray magazine. Thus, when the input magazine is charged by an operator, the assembly is capable of a long-term unattended operation.

Typically used are JEDEC standard trays carrying 10 integrated circuits in 8 rows, i.e. up to 80 integrated circuits.

The grippers are preferably provided with extension means for extending each gripper from and retracting it to the holder.

The holder is preferably constituted by a rectangular frame having two spaced pivoted beams pivoted centrally on the axis of rotation and respectively interconnected by two parallel connecting beams, wherein grippers of said plurality of grippers are respectively mounted on each of said two parallel beams, and wherein the holder and tray transporter are arranged in such a way that, when this tray is in the operational position, at least some of the integrated circuits in a tray are engageable by grippers of said plurality of grippers rotated to the first angular position.

Alternatively, the holder can be constituted by a oblique-angled frame (e.g., a trapezoid frame) having two spaced pivoted beams pivoted centrally on the axis of rotation and respectively interconnected by two tapering connecting beams, wherein grippers of said plurality of grippers are respectively mounted on each of said two tapering connecting beams, and wherein the holder and tray transporter are arranged in such a way that, when this tray is in the operational position, at least some of the integrated circuits in a tray are engageable by grippers of said plurality of grippers rotated to the first angular position.

In the above context, a handling assembly can transfer integrated circuits from a tray to a receiving/releasing means. This operation will proceed by the following stages: the tray transporter places a tray to a position in which a group (e.g., a row) of integrated circuits can be gripped, the manipulator grips the integrated circuits by rotating the holder to the first angular position and activating the grippers, the holder is turned to the second angular position, and the integrated circuits are received by the receiving/releasing means which can be constituted by test sockets of a testing apparatus, wherein the test sockets are spaced in correspondence with the grippers. The integrated circuits received in the sockets undergo testing to determine a quality category of each integrated circuit. Standard sockets, e.g. by Enplus Corporation, USA, can be used in conjunction with the testing means of the present invention.

A testing apparatus is a device for applying test signals of a predetermined pattern to the integrated circuits under test, receiving response signals and attributing each tested integrated circuit, according to its test results, to one of quality categories. Generally, a testing apparatus includes a test generator, fault logic device and a test header comprising test sockets for receiving integrated circuits under test, the test header serving to provide electrical communication between the integrated circuits under test and said test generator and fault logic device. Preferably, the number of the test sockets is equal to the number of integrated circuits in a row of a tray, and to the number of integrated circuits which can be tested at a time by the testing apparatus. However, if the testing apparatus can test more integrated circuits, an additional integrated circuit manipulator can be incorporated. For example, in the preferred embodiment described below the number of test sockets is 10, the number of ICs which may be tested at a time by the testing device is 20, and the number of the integrated circuit manipulators is 2. Such an arrangement enables to reduce the overall testing time by reducing or eliminating the down times of the testing device.

When the testing is over, the handling assembly can transfer integrated circuits from the test sockets back to the tray. This operation will proceed by the following stages: the manipulator grips the integrated circuits from the test sockets by rotating the holder to the second angular position and activating the grippers, the holder is turned to the first angular position, and the integrated circuits are released to be received in the tray placed by the tray transporter to a position in which integrated circuits can be received in the tray. Then the tray transporter will move the tray to place it to a position in which another row of integrated circuits can be gripped.

However, the handling assembly can be used for other purposes, e.g. sorting the tested integrated circuits. In the most simple case there are two categories of “pass” and “failure” integrated circuits. However, with the handling assembly the of the present invention, ICs can be separated into an unlimited number of categories representing various levels of quality.

For this purpose, the manipulator which will selectively grip tested integrated circuits of the same category and transfer them to the receiving/releasing means which in this case can be constituted by the inclined rail means along which they will slide down by their own weight. In this case, the oblique-angled holder (to match with the inclined rail means) shall be used in the manipulator.

Here, another (downstream) handling assembly can be used for receiving the selected integrated circuits belonging to the same quality category and placing them into a tray. When all the tested integrated circuits of this quality category are thus removed from one tray and placed into another, the upstream handling assembly will selectively grip tested integrated circuits of another category and transfer them to the downstream handling assembly which will place them into another tray moved to the operational position by the tray transporter.

Thus, the handling assembly of the invention is a multi-purpose handling assembly which can perform either of the above three operations. Therefore, a handling apparatus can be built up of these handling assemblies connected with one another.

In accordance with another aspect of the present invention, claimed is a handling apparatus for handling integrated circuits and trays for receiving thereof, the apparatus comprising a first handling assembly and a second handling assembly, wherein each of the first and the second handling assemblies is constituted by a handling assembly for handling integrated circuits and trays for receiving these integrated circuits, the handling assembly comprising at least one integrated circuit manipulator having a holder pivoted on a fixed axis of rotation; the holder having a plurality of grippers arranged substantially in the plane passing through said axis of rotation, the holder being adapted to rotate said plurality of grippers at least to a first and second angular positions; a tray transporter adapted to move a tray into an operational position in which at least one of the integrated circuits in the tray is engageable by one of the grippers rotated to the first angular position, and a rail means engageable by at least one of the grippers rotated to the second angular position, wherein said inclined rail means are common for both handling assemblies, so that the handled integrated circuits can slide down along the rail means from the first handling assembly located upstream to the second handling assembly located downstream. In this embodiment, the handling apparatus can perform the operations of separating the tested integrated circuits by quality according to their test results, and placing the tested integrated circuits in trays for discharging.

The handling apparatus can further comprise a third handling assembly disposed upstream of the first handling assembly, wherein the tray transporters of the first handling assembly and the third handling assembly are joined together. In this embodiment, the handling apparatus can further perform the operation of receiving a tray of integrated circuits to be tested and transporting the tray to an operational position where the integrated circuits are transferred from the tray to test sockets of the testing apparatus and back to the tray.

Here, for better understanding, the first assembly can be referred to as “the sorting assembly”, the second as “the packing assembly”, and the third as “the testing assembly”.

Alternatively, ICs from the rail means can be packed into tubes. For this purpose, the packing assembly can be omitted, and a tube installed directly at the output of the rail means. Any known equipment can be used in this connection, e.g. as proposed in PCT/RU98/00380 by the same applicant.

Among significant advantages of the invention are: high throughput (of up to 35,000 units per hour), extended period of unattended operation, and serviceability due to a compact and operator-friendly arrangement. A standard size tray is used for transporting ICs through the handler resulting in an improved reliability and avoiding the operation of handling ICs between customer trays and test trays.

Other advantages of the handling system will be apparent from the following detailed disclosure of the invention accompanied with drawings.

### BRIEF DESCRIPTION OF THE SEVERAL VIEWS OF THE DRAWING

For a better understanding of the present invention and to show how the same may be carried into effect, reference will now be made, by way of example, to the accompanying drawings in which:

FIG. 1 is a side view showing a handling apparatus according to the present invention;

FIG. 2a is a plan view of an example tray magazine, and FIGS. 2b-2d are side elevation views illustrating the operation of the first embodiment of the tray magazine;

In FIG. 3 a plan view and two side views of another embodiment of the tray magazine;

FIG. 4 shows the joined tray transporters of the testing assembly and the sorting assembly;

FIG. 5 is a side view of the testing assembly;

FIG. 6 shows a plan view of the reversible frame of the IC manipulator for the testing assembly, and elevation views of a suction gripper;

FIG. 7 is a perspective bottom view of the test header;

FIG. 8 is a side view showing an embodiment of the sorting assembly coupled with the packing assembly;

FIG. 9 shows a holder of the IC manipulator for the sorting assembly in greater detail;

In FIG. 10 a holder of the IC manipulator for the packing assembly is shown with a cut-away gravity rail;

FIGS. 11a-d show a longitudinal section of the gravity rail, its enlarged part, a plan view of the gravity rail and various sectional views of the gravity rail;

FIG. 12a is a side view of an alternative embodiment of the apparatus, and FIG. 12b illustrates the operation of the embodiment of FIG. 12a.

### DETAILED DESCRIPTION OF THE INVENTION

1. General Description of the Handling Apparatus

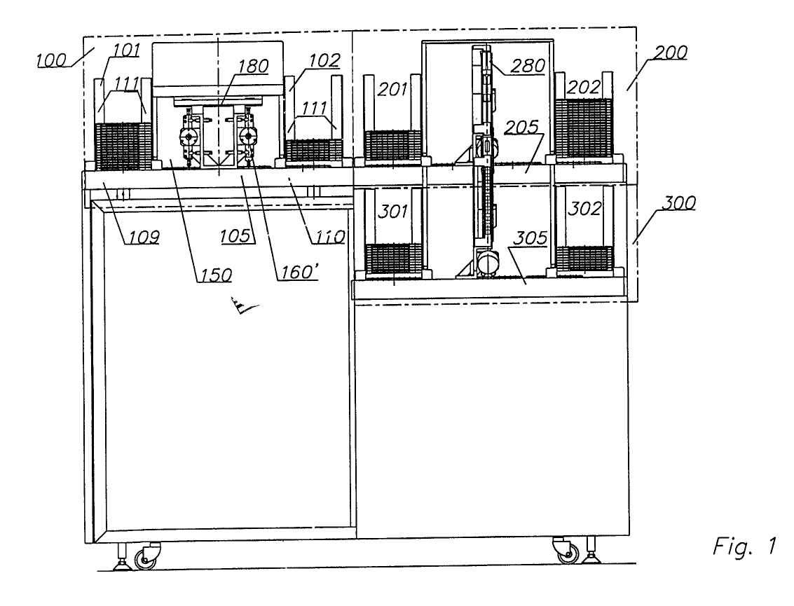

A handling apparatus for handling integrated circuits and trays for receiving thereof in accordance with the preferred embodiment of the present invention shown in FIG. 1 has a modular structure and comprises a testing handling assembly 100, a sorting handling assembly 200 and a packing handling assembly 300. These handling assemblies, connected by a common transport path, form a single ICs processing line. Thus, preferably, the testing assembly 100 is further supplemented by a sorting assembly 200 which is actually an extension of the testing assembly 100, whereas the sorting assembly can further be supplemented by a packing assembly 300 which is actually an extension of sorting assembly 200. At the same time, each of these assemblies can also function separately and independently.

It shall be understood that the handling apparatus can be arranged in many other configurations by adding or omitting handling assemblies and changing receiving/releasing means.

The preferred embodiment of the present invention is designed to operate using the same container for ICs throughout the whole process, which is preferably a customer tray, in particular, the JEDEC standard tray. It will be appreciated that the handling apparatus of this invention can operate with customer trays of different size and capacity having rectangular pattern of packing, i.e. wherein ICs are contained in cells arranged in a horizontal plane in rows and columns. Each customer tray is open at the top to expose ICs so that they can be accessed by the IC manipulator of the present invention. It shall also be mentioned that standard trays are usually provided with keys showing their orientation for further identification of ICs during testing, sorting and packaging.

Referring back to FIG. 1, the testing assembly 100 comprises an input tray magazine 101 and an output tray magazine 102 adapted to receive customer trays, a tray transporter 105, and a thermostat chamber 150 with a IC manipulator 160 and a test header 180 therein. The input 101 and output 102 magazines are arranged on an upper mounting level of a cabinet frame over respective input 109 and output 110 areas of the tray transporter 105.

Each tray magazine has a rectangular box-like structure defined by corner guides 111 for holding trays in a stack, and is open from the top and from the bottom so that trays can be added and taken away as desired. The IC manipulator 160 is arranged over the transporter 105, and is operable to pick ICs from a tray, bring them into contact with the sockets of the header 180 and return them back to the tray. The tested ICs in customer trays are stacked in the output magazine 102 or transported directly to an input area of the sorting assembly 200.

Referring now to the sorting assembly 200 and the packing assembly 300, it shall be mentioned that their configuration is generally similar to that of the testing assembly 100. Therefore, similar elements in the drawings are designated with similar position numbers.

A stack of trays filled with tested ICs is loaded to the input of the sorting assembly 200. Alternatively, trays can be received directly from the testing assembly 100. An IC manipulator 260 of the sorting assembly extracts from the tray ICs of a certain quality category and places them to a gravity rail 280 along which the ICs slide down to the packing assembly 300. The sorting assembly 200 is operable to select ICs of only one current quality category. The transporter 205 is reversible, i.e. adapted to move the trays in both directions. For example, as soon as the last tray of a loaded stack has been processed, the transporter 205 is switched automatically to transfer the trays in reverse direction to extract ICs of the next desired quality category from a tray flow. In this case assemblies 100 and 200 operate separately. The trays are passed through the sorting assembly 200 as many times as there are quality categories.

It will be appreciated that a plurality of sorting assemblies 200 (preferably, combined with respective packing assemblies 300) can be employed in a processing line to provide a high throughput of the testing assembly 100, for example, the number of sorting assemblies 200 (with respective packing assemblies 300, if desired) may be equal to the number of quality categories. One-way transporters 105 and 205 can be used in this case.

The sorted ICs of one current quality category are tansferred to the packing assembly 300 via the gravity rail 280. A stack of empty trays is installed into the input magazine 301. An IC manipulator 360 of the packing assembly places ICs of a certain quality category into the trays, and the trays filled with sorted ICs are stacked in the output magazine 302. This operation is performed with respect to one quality category after another synchronously with the operation of the sorting assembly 200. Thus, ICs of different quality categories never meet on one tray while packing.

To reduce manual operation, automatic transportation of empty trays from the sorting assembly 200 to the packing assembly 300 can be performed according to the proposed invention. For this purpose assemblies 200, 300 can be provided with respective tilters 40, 50 which operation will be described hereinafter.

2. Detailed Description of the Testing Assembly 100

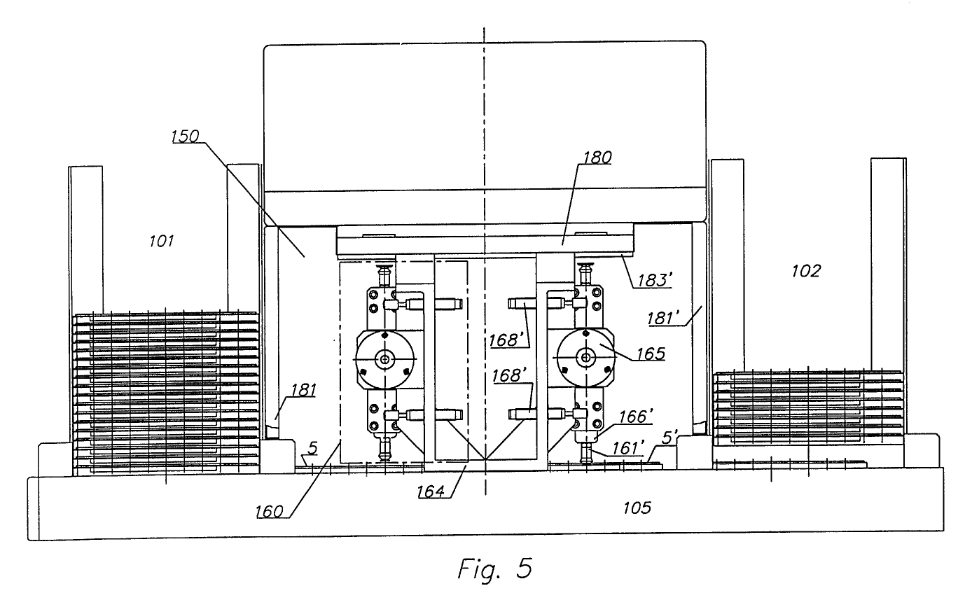

The testing assembly 100 shown in FIG. 5 comprises an input tray magazine 101 and an output tray magazine 102, each tray magazine having a tray elevator 104; a tray transporter 105; and, enclosed in a thermostatic chamber 150, two IC manipulators 160, 160′ and a test header 180.

3. Detailed Description of the Input/Output Magazines

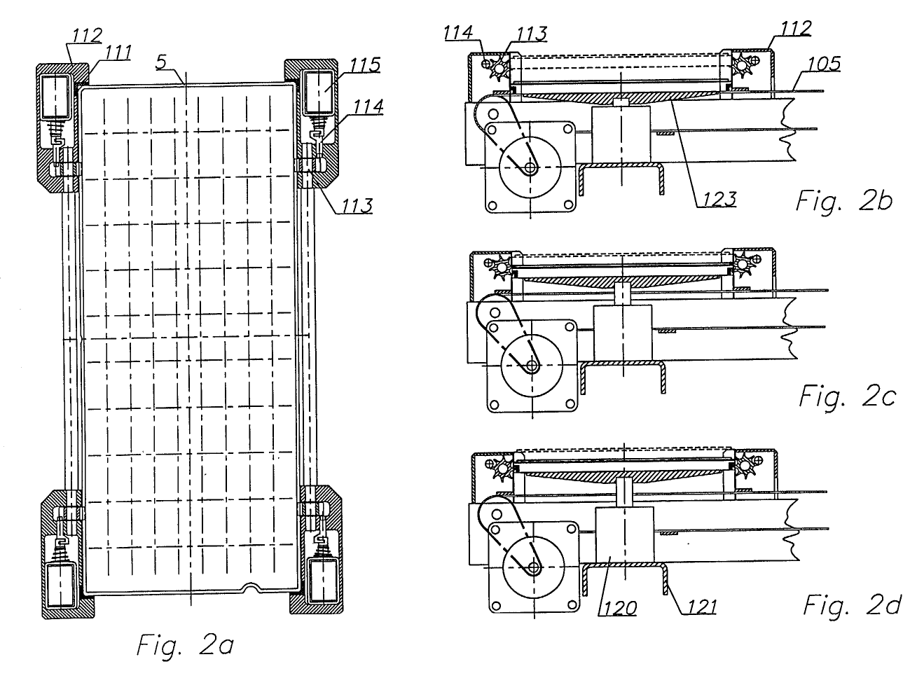

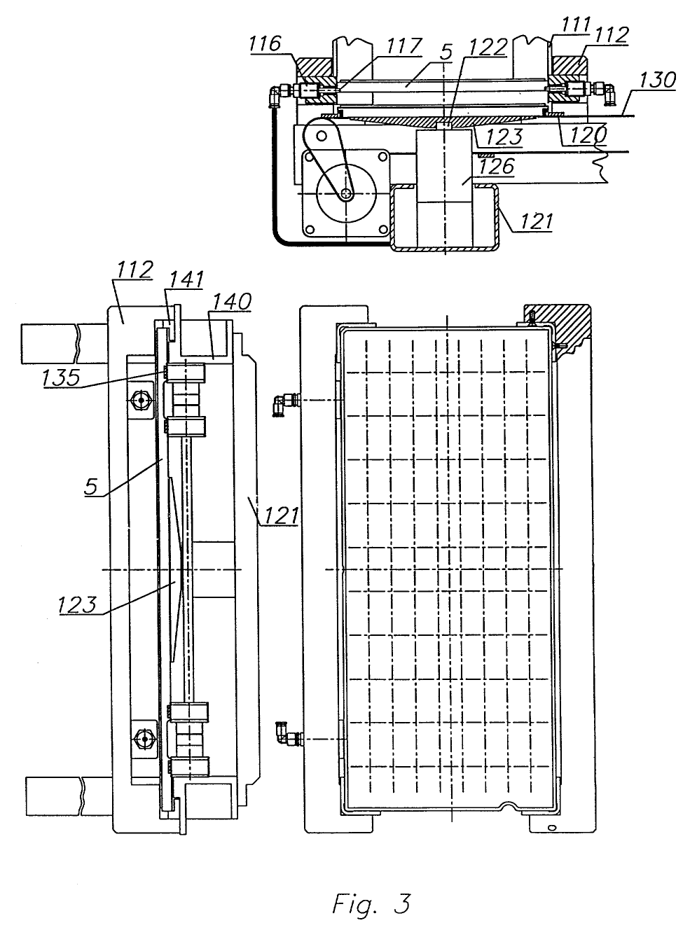

As shown in FIG. 2a, the tray magazine comprises four corner guides 111 which support a stack of trays 5, the guides being made, e.g. of an angle bar. The guides 111 are mounted substantially vertically by means of brackets 112. Each tray magazine is provided with a holding means 113,114 adapted to retain a stack of trays while taking down the lowermost tray of the stack and thus enabling loading and/or unloading the trays one by one from below.

The holding means shown in FIGS. 2b-2d are constituted by four cog-wheels 113 the cogs of which hold the tray in the stack. The cog-wheels 113 are provided with an extendible/removable stoppers 114 driven by a solenoid 115. During the loading/unloading operation, the stoppers 114 are removed by solenoid 115 to disengage the cog-wheels enabling their free rotation and elevation/lowering of the tray by means of the tray elevator plate 123. When the tray is positioned on a desired height (as shown in FIG. 2d), the stoppers 114 engage the cogwheels that fix the tray within the stack. All the movements of the holding means and other mechanisms of the handler are controlled by the central processing unit.

Alternatively, the tray magazine and the holding means can be in the form of extendible/removable pins 117 as shown in FIG. 3. During the loading/unloading operation, the pins are retracted by pneumatic power cylinder 116 to release the lowermost tray of a stack. It shall be mentioned that various modifications of the holding means and the tray magazine can be designed by a person skilled in the art.

4. Detailed Description of the Tray Elevator

As shown in FIG. 1, each magazine 101, 102 has its respective tray elevator 104, 106 illustrated in detail in FIG. 2 or FIG. 3. It comprises a substantially vertical pneumatic power cylinder 126 (or, alternatively, a stepper motor) arranged on a cross-bar 121 mounted on the cabinet frame, a movable rod 122 of the cylinder 126 having a plate 123 arranged on its top. The plate 123 is dimensioned so as to pass between the guides of the tray magazine 101/102 forming, however, a durable support for a tray or a stack of trays. Thus, the plates 123 in this embodiment of the invention are circular.

The generally vertical stroke of the tray elevator is defined by the lowermost position and the uppermost position, respectively, of the plate 123. The lowermost position of the plate 123 is defined in such a way that its substantially horizontal upper surface is located somewhat below a lower surface of a tray laying on the transporter 105. The uppermost position of the plate 123 is defined so that the upper recesses of the lowermost tray supported by the elevator plate are positioned somewhat higher than the pins 117 or the cog-wheel 113, so that the lowermost tray can be taken onto the plate, or a next tray can be placed over the stoppers.

5. Detailed Description of the Tray Transporter

The substantially horizontal tray transporter 105 is designed to move trays 5 filled with ICs from the input tray magazine via a test area to the output tray magazine. The transporter 105 is arranged on the cabinet frame so that its longitudinal axis lays in a common plane with vertical axes of input/output magazines 101,102. This simplifies the alignment of the trays.

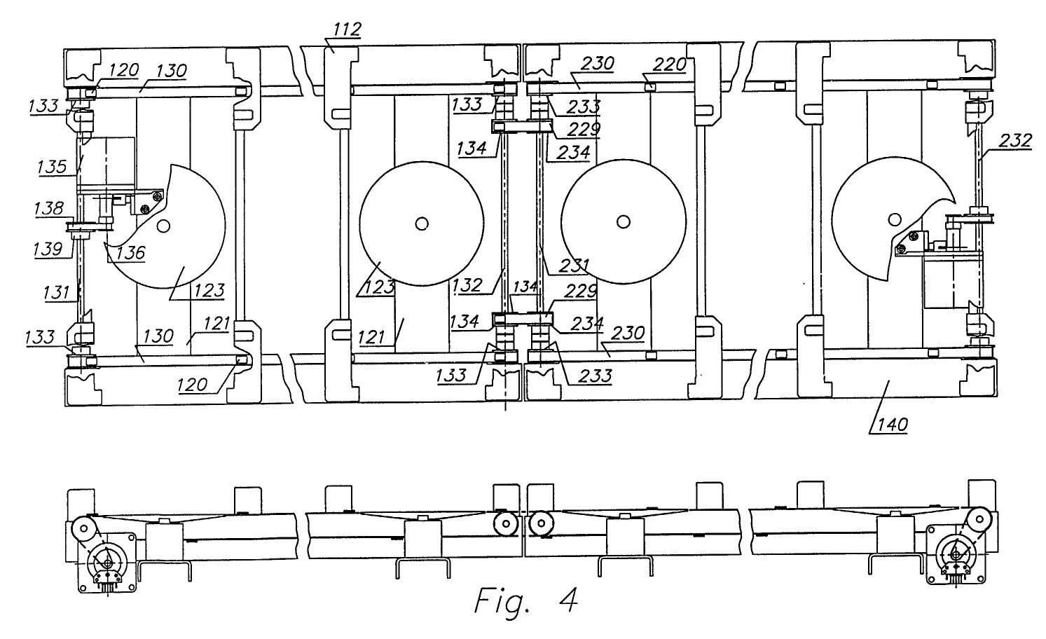

As shown in detail in FIG. 4, the transporter is belt-type, and comprises two identical toothed conveyor belts 130; two respective shafts 131 and 132 with rollers 133 thereon; belt guide means (not shown) for supporting the belts; and driving means 135. Two similar generally horizontal supporting bars 140 are mounted on cross-bars 121, aligned in a horizontal plane and spaced at a distance generally equal to a transverse dimension of a tray 5. To ensure the tray positioning in a transverse direction with a desired accuracy, each bar 140 is provided with a guiding element 141 (see FIG. 3) attached thereto. The length of bars 140 shall be chosen so as to provide that a portion of the conveyor belt 130 extends beyond the input/output tray magazines.

Referring back to FIG. 4, the shafts 131, 132 are mounted in bearings arranged at the ends of the respective bars 140. Rollers 133 are fitted on the shafts 131, 132 in a common generally horizontal plane. Each pair of the rollers 133 adjacent to a separate inner wall of the bar 140 is wrapped by a respective toothed belt 130. The two belts 130 together form a conveyor for transporting trays thereon. Rollers 133 are provided with bounding ribs and slots to ensure driving the toothed belt 130 without slipping. It shall be appreciated that a belt 130 tooth pitch is equal to a roller 133 slot pitch. Preferably, outer surfaces of the belts 130 are provided with elastic fixing ribs 120 which project outwardly, the distance between mutually faced sides of said ribs being equal, with a desired accuracy, to a transverse tray dimension so that to a tray can be fitted between these ribs. The width of said ribs is such that a distance between two boundary rows of ICs in two adjacent trays is a multiple of a tray interrow interval. The ribs 120 are not very heigh to avoid interfering the belt movement, and are formed of elastic material, such as polymer and can be e.g., glued to the conveyor belt with a suitable adhesive or moulded integrally with the belts 130. It will be appreciated that the ribs are aligned on both conveyor belts 130 to receive a tray without misalignment.

The transporter 105 is provided with a belt guide means (not shown) fixed onto the bars 140 to support the belt with the trays thereon and eliminate deflection of the belt under various static and dynamic loads. These guide means can be implemented, for example, as support rails manufactured from a material with a low friction factor e.g. conductive plastic, such as electroless nickel-Teflon.

To ensure precise positioning of the trays, an electric (e.g. stepper) motor 135 is arranged on one of the cross-bars 121. The rotational moment of the motor 135 is transmitted to shafts 131,132 via a slotted pulley 136 fitted on the motor shaft, an auxiliary toothed belt 138 and a slotted pulley 139 fitted on one of the transporter shafts 131, 132 between the rollers 133. The arrangement of said auxiliary toothed belt transmission is generally similar to the arrangement of the toothed belt transporter 105.

6. Detailed Description of the IC Manipulator

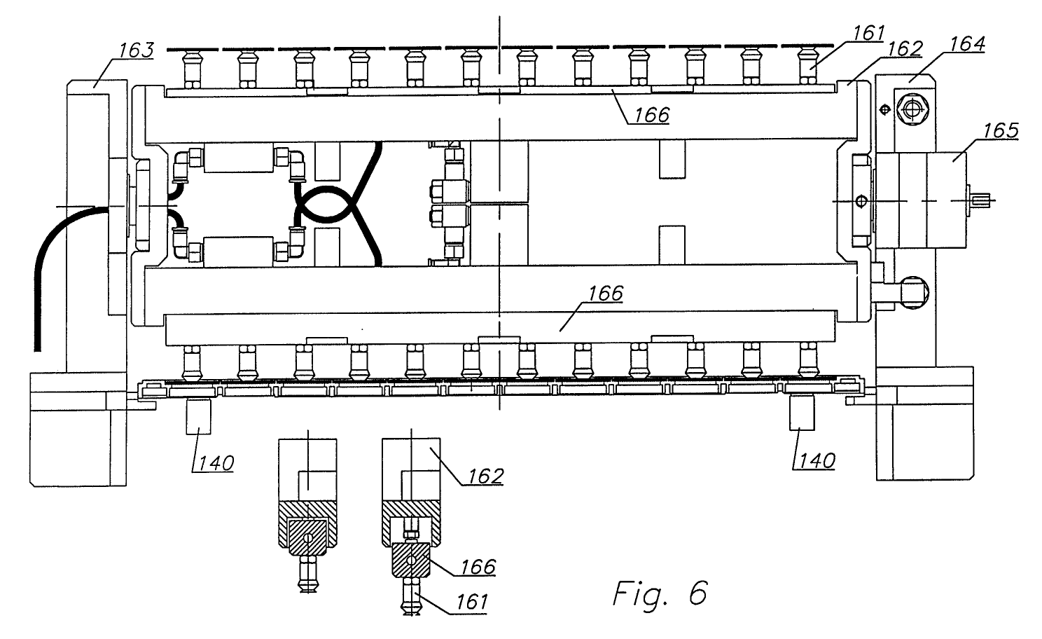

The IC manipulator 160 shown in FIGS. 5 and 6 takes a row of ICs from a tray 5, inserts the ICs into sockets of a test header 180 and, after testing, returns the ICs to the same tray or, in some cases, to the next tray as will be described hereafter. In a preferred embodiment of the invention two IC manipulators 160 are installed in series to improve the apparatus throughput.

As shown in FIG. 6 in more detail, the IC manipulator 160 comprises a holder constituted by a generally rectangular frame 162 having two spaced pivoted beams pivoted centrally on racks 163, 164 defining their axis of rotation and respectively interconnected by two parallel connecting beams with two rows of suction grippers 161 respectively mounted on each of them. One of the pivoted beams of the frame 162 is pivoted in a bearing incorporated in the rack 163, while another pivoted beam is directly coupled with a driving means, e.g. a stepper motor 165 or pneumatic activated motor, incorporated in the rack 164.

Both manipulators 160, 160′ are arranged on the upper level of the cabinet frame over the processing area of the transporter 105. Here, for the purposes of explanation, a processing area means an area defined by the operational distance of the IC manipulator. When a tray is located in this area, it is considered to be in an operational position in which integrated circuits in the tray are engageable by the grippers of the manipulator. It shall also be appreciated that the IC manipulators 160, 160′ are spaced from each other and input/output magazines to avoid interference during operation.

The racks 163, 164 are arranged on the upper level of the apparatus on both sides of the supporting bars 140 and between the input 101 and output 102 magazines, so that the axis of rotation of the frame 162 extends generally horizontally and perpendicularly to the longitudinal axis of the transporter.

The frame 162 and the tray transporter are arranged in such a way that, when a tray is in the operational position, at least some of the integrated circuits in a tray are engageable by grippers of said plurality of grippers rotated to the first angular position The frame driven by the driving means 165 can be turned by 180° from its initial generally vertical angular operational position to its reversed generally vertical angular operational position and vice versa. Two shock-absorbers 168 are arranged on the rack 164 to absorb inertial forces of the frame 162 and reduce inertial load on the stepper motor 165 while stopping.

The suction grippers 161 of each parallel connecting beam of the frame 162 are preferably provided by extension means constituted by a retractable bar 166 which can be moved between its extended and retracted position. When the frame is in one of its operational positions, and the retractable bar 166 on the lower parallel connecting beam is in its extended position, the suction grippers 161 can reach and grip ICs from a row in a tray 5′ positioned on the transporter 105 directly below these grippers. When the bar 166 is retracted, the frame can be rotated freely, i.e. without interference with the other equipment. Similarly, when the parallel connecting beam turns up and comes to its upper position, the retractable bar can be moved to its extended position to insert the ICs gripped by the suction grippers into the sockets of the test header 180 arranged above the IC manipulator 160.

The retractable bar 166 of the frame 162 can be driven electrically or pneumatically.

Each suction gripper 161 is provided with a pipe having its one end connected to a common pipeline, and another end opened to the ambient atmosphere of the thermostat chamber 150. The pipeline is communicated via an electromagnetic valve with a negative pressure source. The negative pressure can be created using, for example, ejection of pressurized air. The negative pressure source generates suction force so that, when the grippers 161 connected to the pipeline are in precise and close contact with any smooth surfaces, in this case, the upper surfaces of ICs, they are attracted to these surfaces under the influence of this suction force and thus can transport these ICs. To release the ICs, the pipes of grippers 161 are connected with the atmosphere by means of the respective electromagnetic valve. Preferably, each pipeline or the common pipeline is provided with a pressure sensor for controlling the suction force. The suction grippers are well known in the industry and are described in details, for example in U.S. Pat. No. 5,961,168.

It will be appreciated that the number of suction grippers 161 is essentially equal to the number of the sockets of the test header. It shall also be noted that, theoretically, the number of suction grippers shall also be equal to the number of ICs in one row of a tray. However, in some cases the number of ICs in one row of a tray can exceed the number of sockets available on the header. To match the header and the trays used, two or more manipulators can be installed, so that the total number of suction grippers would cover the number of ICs in a tray row.

In accordance with the present embodiment, the testing apparatus header 180 is arranged horizontally over the IC manipulator 160, as shown in FIG. 5. However, it is appreciated that the test header (or an additional test header) can be mounted to match any angular position of the IC manipulator. E.g., two test headers can be positioned on both sides of the IC manipulator.

The testing apparatus header is electrically connected with a test system (not shown) which includes a test signal generator for supplying a test signal to ICs pins via sockets 183 and a signal comparator for analysing the results of the test. Based on these results, each specific IC on a tray is assigned its virtual identification tag to enable subsequent sorting. The information about test results and the location of each chip is supplied by means of testing apparatus software to the control unit to be used later during the sorting operation.

As shown in FIG. 5, the header 180 is mounted generally horizontally by supports 181 at a level that allows the IC manipulator 160 to bring ICs into contact with sockets 183, when the retractable bar 166 is in its extended position, and to eliminate interference of the ICs held by suction grippers 161 with the header 180, when the retractable bar 166 is in its retracted position.

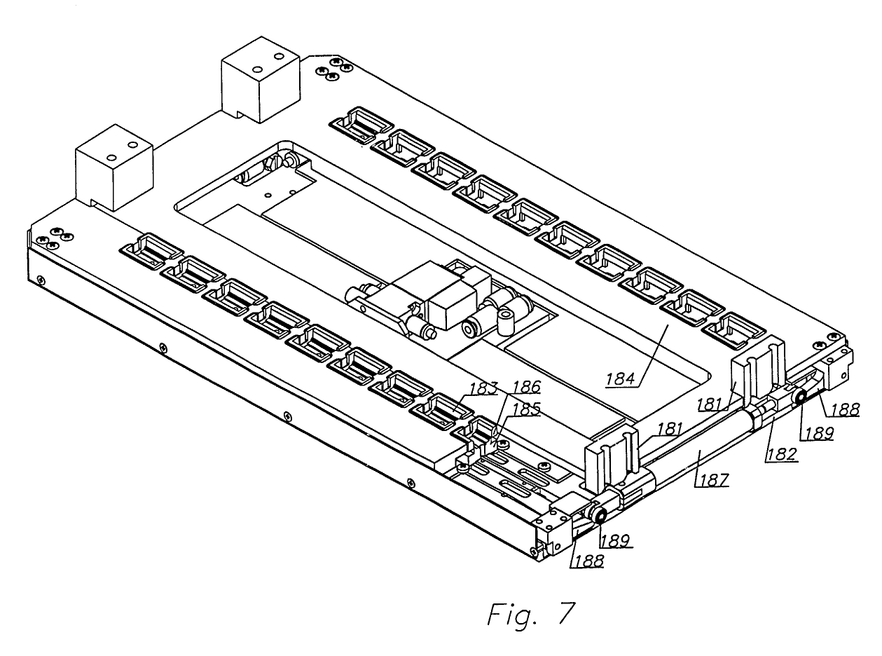

As best shown in FIG. 7, the header 180 preferably comprises two rows of sockets 183 adapted to provide electric contact of ICs with the header. In the preferred embodiment of the present invention sockets with clamping contacts, e.g. OTS-54-0.8-0.1 (TSOP-54) manufactured by Enplus Corporation are used. This socket comprises a stationary part 185 with contacts and a movable spring loaded part 186 that clamps IC pins. To release the pins, the spring loaded part 186 shall be pulled. It shall also be understood that other types of contact sockets can be used as well.

The header 180 further comprises a socket opening mechanism to provide fast and simultaneous opening and closing the sockets of the header. The socket opening mechanism comprises a stationary plate 182 having two rows of slots for disposing two rows of stationary parts 185 of sockets 183; a moveable plate 184 having respectively two rows of slots for spring loaded socket parts 186; and a driving means for pressing these two parts together to open the sockets. The socket opening mechanism further comprises four wedges 188 arranged in the corners of a generally rectangular movable plate 184 to which wedges a force exerted by driving means 187 is applied. The driving means 187 may be constituted by an electric motor with corresponding intermediate links, or a loose pneumatic activated power cylinder having rollers 189 on its ends to provide two moveable points to which the force is applied. The rollers 189 push the wedges 188 which pull the moveable plate 184 and thus, releases the spring loaded contacts of sockets 183 permitting the insertion or extraction of the IC.

It shall also be mentioned that the IC manipulator 160, the header 180 and a respective portion of the tray transporter 105 are enclosed in the thermostat chamber 150 provided with ports for the transporter 105. The thermostat chamber eliminates temperature variation and damaging chimney effect. There are various known thermostat chambers in an electronic industry that can be used in the proposed device. The chamber 150 is controlled in the range of −55° C. to +120° C. with an accuracy of ±2° C. and provides enough thermal soak path to ensure constant temperature of the ICs while testing. An electric heater may be used to obtain elevated temperatures, while low temperatures may be reached by means of liquid nitrogen.

7. Detailed Description of the Sorting Assembly

The sorting assembly 200 is designed to sort the tested ICs in accordance with their test results into any desired number of quality categories, and is generally coupled with the packing assembly 300. As shown in FIG. 1, the sorting assembly 200 comprises a transporter 205 for transporting the trays carrying the tested ICs therein. This transporter is similar to the transporter 105. The sorting assembly 200 further comprises input and output tray magazines 201, 202 which are generally similar to input 101 and output 102 magazines, and an IC manipulator 260 for picking up the tested ICs from the customer trays and placing them into an inclined gravity rail 280 along which the ICs slide down to the packing assembly. The sorting assembly is arranged on the same level as the testing assembly 100 and aligned therewith, so that the transporter 205 is joined with the transporter 105.

In one of the possible modifications, when the number of IC manipulators corresponds to a number of sorting groups, a link element is provided, as shown in FIG. 4, to ensure the automatic transfer of a tray 5 from the transporter 105 to the transporter 205 without slipping and misalignment. The link element is formed by abutting portions of both transporters 105,205 with two auxiliary toothed belts 229 provided with fixing ribs 220 similar to the ribs 120 of the toothed belt 130. Each belt 229 wraps two auxiliary cogged pulleys 134, 234 fitted on a certain distance inward from the main pulleys 133, 233 on the same shafts as the main pulleys. Respectively, each cogged pulley 134 is fitted on the shaft 132 of the transporter 105, and each cogged pulley 234 is fitted on a shaft 231 of the transporter 205.

The distance between the shaft 132 and the shaft 231 is defined by a developed length of the belt 229 which is selected so as the ribs of both belts 229 are aligned with ribs of belts 130 and 230.

8. Detailed Description of the IC Manipulator

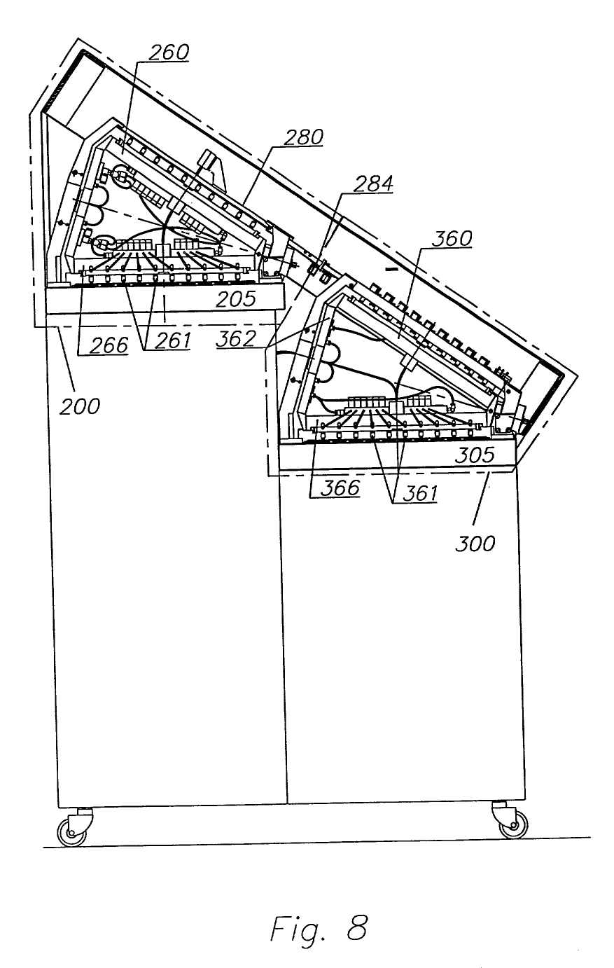

The IC manipulator 260 is arranged on the upper level in the intermediate position in relation to the input/output magazines 201, 202 over the processing area of the transporter 205 and in the plane of the longitudinal axis of the gravity rail 280 to provide the shortest transport path of the ICs on their way from trays of the tray flow to the gravity rail 280 as shown in FIG. 8.

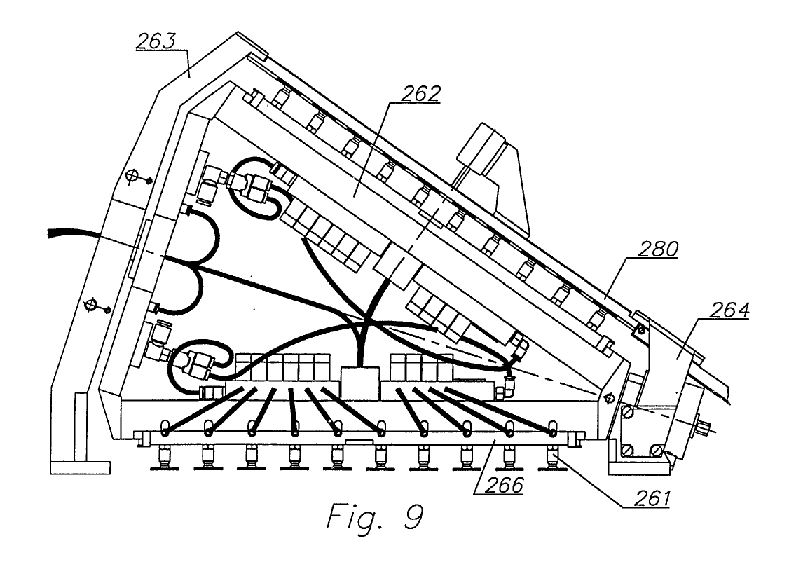

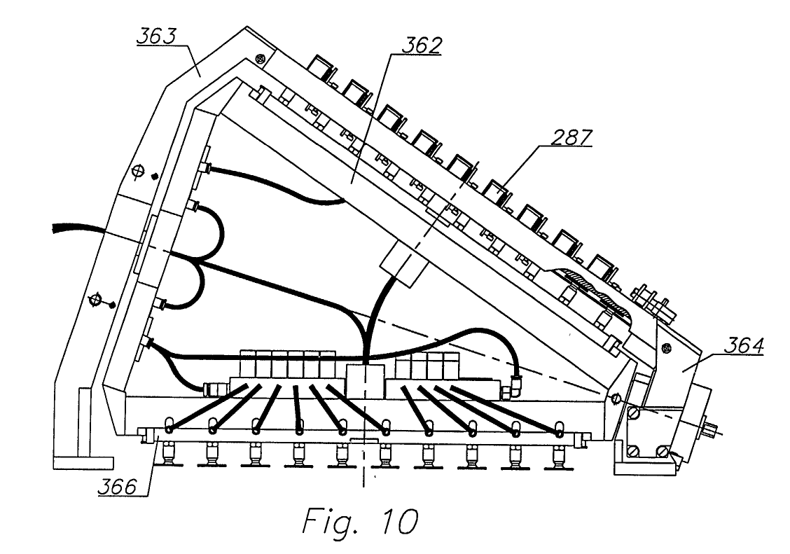

Referring now to FIGS. 8 and 9, the design of the IC manipulator of the sorting assembly will be discussed in more detail. The IC manipulator 260 of the sorting assembly comprises a reversible frame 262 with an inclined pivot axis. The angle of inclination of the pivot axis is defined as α/2 and is equal preferably to 17°30′, where α is an angle of inclination of the gravity rail to horizon which is preferably 35°. The frame 262 is generally oblique-angled, and is mounted on racks 263, 264 of uneven height that may be also inclined. It is appreciated that the term <<oblique-angled>> includes generally three-cornered, trapezoid, or any other tapered plane shapes.

The suction grippers of the reversible frame 262 are preferably mounted on retractable bars 266, every suction gripper 261 of the IC manipulator 260 having individually controlled catch and release action to prevent gripper failure while taking only separate ICs from a row.

9. Detailed Description of Gravity Rail

As shown in FIG. 8, the gravity rail 280 provides a simple means for transportation of sorted ICs from the sorting assembly 200 to the packing assembly 300 with the use of gravitation. It shall also be mentioned that the sorting assembly in conjunction with the packing assembly 300 can also be used for transferring IC from the trays of one type onto the trays of another type. Also, these two assemblies can be used to rearrange ICs on the trays in a desired order. For example, to obtain trays in which ICs are packed only in odd rows, the sorting assembly may be used to pick up all the IC from even rows, while packing assembly may be used to pack the taken out ICs back into trays, but now, into odd rows only.

The rail 280 is arranged in an inclined position at an angle α which in this embodiment may vary from 20° to 40°, preferably 35° with respect to horizon. At greater angles of inclination the likelihood of damage to the IC pins increases, while at lower angles the friction between the ICs and the rail 280 may exceed the gravity component directed along the rail that would interfere or prevent IC from sliding down the rail 280.

As shown in FIG. 8, the rail 280 lays in the generally vertical plane coinciding with the operational planes of both the IC manipulator 260 and the IC manipulator 360 of the sorting assembly, and is substantially perpendicular to the longitudinal axis of the transporter 205.

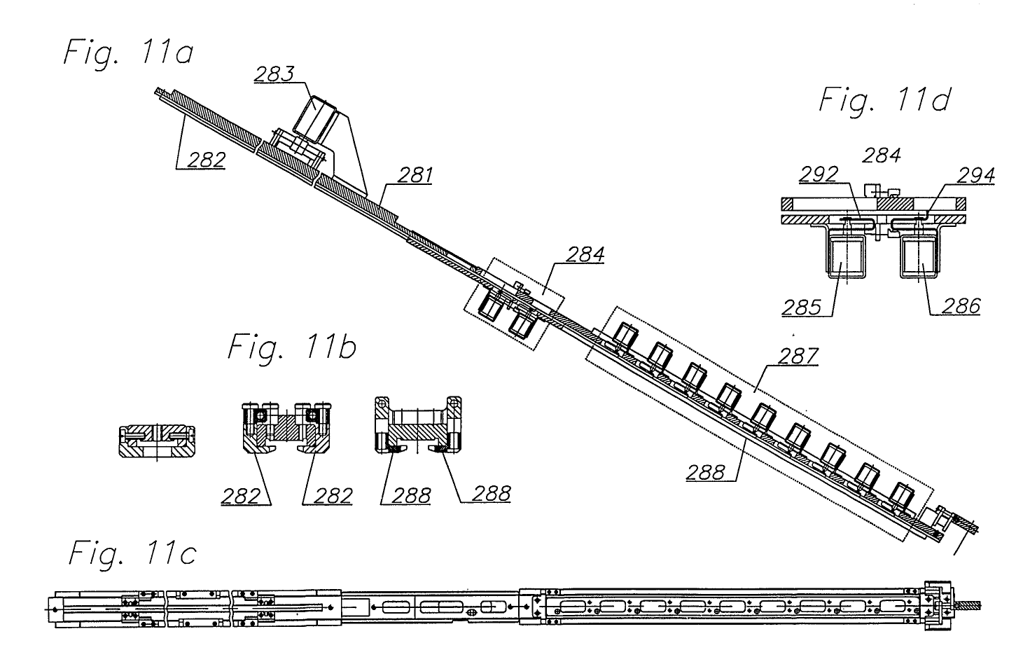

As illustrated in more detail in FIGS. 11a-11d, the rail 280 comprises a bar 281, input flaps 282 with their driving means 283, output flaps 288 with their driving means (not shown), a singularizing means 284 and positioning stoppers 287.

The rail 280 is mounted on the inclined racks 263, 264 and 363, 364 in parallel to the upper connecting beam of the manipulator frame 262, so that its input upper area, or the area where the input flaps 282 are arranged, is positioned exactly over the suction grippers 261 of the sorting assembly 260, while its output lower area, or the area where the output flaps 282 are arranged, is positioned exactly over the suction grippers 361 of the packing assembly. The rail 280 is spaced from manipulator frames by a distance that allows to insert and take out ICs from the rail by the suction grippers of respective manipulators.

The pivotally mounted axially elongated input flaps 282 and similar output flaps 288 are operated by the respective driving means 283, 289 (not shown) which can be implemented in a pneumatically activated motor or a solenoid arranged on the bar 281 and provided with respective known mechanical linkage (such as levers and rods) to said flaps. When the flaps 282, 288 are in their closed position shown in FIG. 11b, a space is reserved therebetween wide enough to pass the suction grippers 261, but small enough to pass the ICs. The inner surface of the input and output flaps forms a sliding surface for the ICs transported from the sorting assembly to the packing assembly through the rail 280.

Loose transporting of the ICs down the rail 280 is effected under gravity. The singularizing means 284 for dividing the IC flow into separate pieces is arranged on the bar 281 in the middle part of the rail between the rail input area and the rail output area. The singularizing means 284 is intended to set a predetermined delay period between each two transported Ics. The singularizing means 284 comprises two stoppers 292, 293, each stopper being formed of a spring-loaded tab for holding ICs and a solenoid for activating the tab.

The lower stopper 293 tab is formed with a notch 291 that projects transversely across the rail, so that when the stopper is de-energized, the spring looses and the notch blocks the rail 280 internal path, while in the activated state the tab is retracted to allow ICs to pass through, as best shown in FIG. 11d.

The upper stopper 292 tab is formed without a notch, so that in its normal de-energized state the stopper does not block the IC path, while in the activated state the tab presses the IC against the inner surface of the rail to prevent the ICs from passing. Alternatively, the singularizing means can be implemented in another manner evident for a specialist in the art.

Structurally, the lower part of the gravity rail 280 belongs to the packing assembly 300, however, for the clarity of explanation, the whole arrangement of the gravity rail will be described in detail herein.

A positioning stopper means 287 is arranged in the output area of the rail 280 for positioning in the output area the ICs of one batch (consisting of the ICs inserted in one operation by the manipulator of the sorting assembly) with a distance that corresponds to the distance between suction grippers of the manipulator frame 362 which is defined in turn by a distance between ICs in a customer tray. The stopper means is designed also to position the ICs in contact with the inner surface of the output flaps 288 within the rail 280 to ensure catching them by the IC manipulator 360 which is structurally similar to the IC manipulator 260.

Alternatively, the stopping action for positioning the IC can also be carried out in other ways, for example, by separate solenoid-activated stoppers working consecutively one after another starting from the lower end of the rail 280, as described in more detail hereinafter. The actuating element of these solenoid activated stoppers is generally U-shaped and formed, e.g. by a sprig-like tag, one part of which is attached to the rail 280. The tag can be positioned in a recess in the rail, the other part being connected to a solenoid rod and provided with an outwardly extended projection. When the stopper is de-energized, this projection prevents the ICs from sliding down the rail 280, while the free part of the stopper presses the IC against the output flaps 288. When the stopper 287 is activated (released), the U-shaped tag is retracted by the solenoid rod to allow the ICs to slide down. Each stopper's position is controlled by a sensor (e.g. an optical sensor, or any other suitable one) which determines the presence of an IC. The first transported IC of this batch can be stopped by a stationary mechanical stop arranged at the end of the rail 280 output area.

10. Detailed Description of the Packing Assembly

The packing assembly 300 is generally similar to the sorting assembly 200 and designed to pack one quality category of separated ICs after another into customer trays. Referring back to FIG. 1, the packing assembly 300 comprises a transporter 305 for empty trays to be filled with the sorted ICs, said transporter being similar to the transporters 105, 205 (in the present embodiment the transporter 305 is not provided with a linkage joining abutted transporters, but such a link can be added if desired), the input and output tray magazines 301, 302 and an IC manipulator 360. The longitudinal axis of the transporter 305 is parallel to the longitudinal axis of the transporter 205.

In the preferred embodiment, as shown in FIG. 8, the packing assembly 300 is arranged on the lower level with respect to the testing assembly 100 and the sorting assembly 200 to provide the ICs to be fed into the sorting assembly 200 under the influence of gravity provided that the frames 262 and 362 are spaced enough to eliminate their mutual interference.

As shown in FIG. 10, the IC manipulator comprises a frame 362 pivoted on inclined racks 363, 364 and provided with suction grippers 361 each having a separate pipeline connected to the negative pressure source.

11. Detailed Description of Tray Tilters

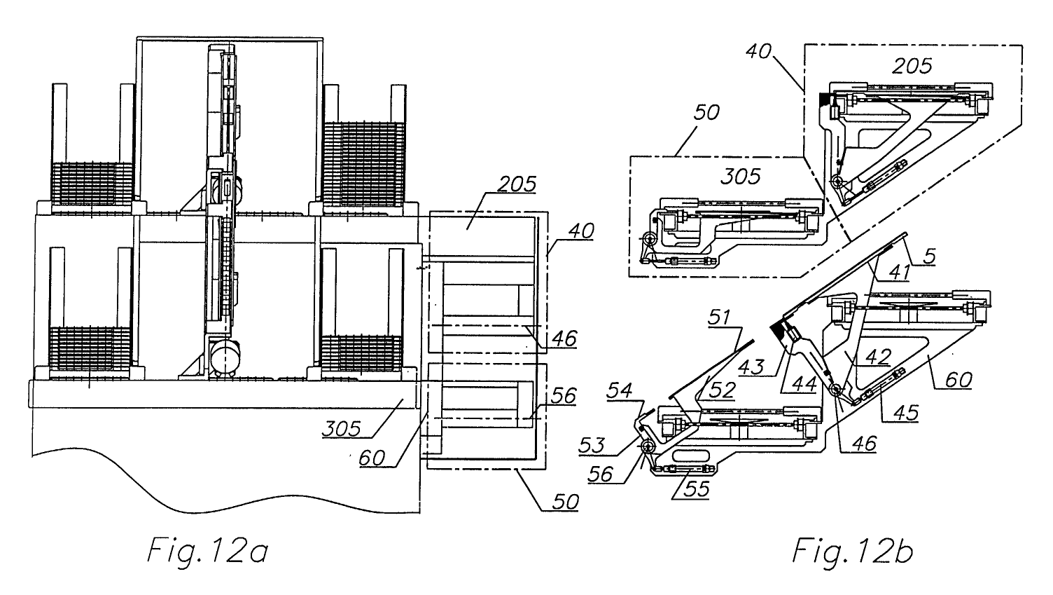

As shown in FIG. 12, the apparatus of the present invention can optionally be provided with tilters 40, 50 for transferring empty trays from the sorting assembly 200 to the packing assembly 300. In this case, the transporters 205, 305 are elongated beyond the output magazines 202, 302 for a distance of a tilting area. Generally, both tilters 40, 50 are pivotally mounted on a common frame 60 which extends from the transporter 205 tilting area to the transporter 305 tilting area generally in the vertical plane.

Referring to FIG. 12, upper tilter 40 comprises a plate 41, a swing main arm 42, a pivotally mounted driving lever 43 provided with a solenoid activated stopper 44 and a driving means 45. The plate 41 is mounted on the upper end of the arm 42 and located so that its upper surface is placed substantially horizontal in the tilting area in line with or below the carrying run of the transporter 205. The plate 41 is generally rectangular and dimensioned so that to hold a tray thereon and to pass between two toothed belts of the transporter without interference. Linked together the arm 42 and the lever 43 are pivotally mounted on a pivot 46 which in turn is arranged on the frame 60 below the transporter 205 in parallel thereto. The upper end of the lever 43 is generally coplanar to the upper surface of the plate 41, its lateral sides being bounded by guiding ribs spaced from each other so that a tray may pass therebetween. Furthermore, the upper surface of the lever 43 is provided with a solenoid activated stopper 44. Both the arm 42 and the lever 43 are configured so that they can be turned to the tilted position around the pivot 45 by a driving means 44 thereby the arm 42 passes through the transporter 205, while the plate 41 is tilted by an upper surface of the lever 43, preferably, on 350 to ensure the tray laying on the plate 41 slides down up to the stopper 45. The driving means 44 can be implemented in a pneumatically activated power cylinder having one end connected to the lever 43 and the other end connected to the frame 60.

The lower tilter 50 which is generally similar to the tilter 40 has a non-activated mechanical stop to position an empty tray 5 in relation to a plate 51 longitudinal edge. Preferably, the plate 51 has lateral guiding wedge-like ribs adjusting the tray position in relation to the transverse axis of the plate 51 while the tray 5 slides down. The mutual arrangement of the tilters 40, 50 is such that the upper surfaces of the plates 41, 51 and levers 43, 53 of both tilters generally lay in a common plane to form a composite sliding surface for the empty tray 5 when both said tilters are in their tilted position.

It will be appreciated that in some modifications the upper tilter 40 can transfer an empty tray directly into the empty tray input magazine 302.

12. An Alternative Embodiment of the Invention

The arrangement of both manipulators 160, 160′ in series allows to process ICs in customer trays in which an ICs column pitch is lesser than the minimal possible test socket pitch on the testing apparatus header 180. The design of the alternative embodiment of the present invention is generally similar to the preferred embodiment with some differences in suction grippers and test sockets arrangement described hereinafter. Thus, the suction grippers of two manipulators are staggered (not shown) so that each manipulator can successively process incomplete rows of ICs belonging to its own columns (even or odd) extended along the longitudinal axis of the transporter. In this case each manipulator frame bar has half as much suction grippers as the manipulators 160, 160′, for example five suction grippers on each bar 166 instead of ten shown in FIG. 6, the reduced number corresponding to the number of ICs in an incomplete row.

In one more alternative embodiment, the IC manipulator frame comprises the same number of grippers, but only half of them is connected to the source of suction power. The suction grippers in staggered rows (or activated in a staggered way) are spaced along the bars of a manipulator frame with a pitch which is generally equal to a double intercolumn pitch, so that said grippers are aligned with ICs of corresponding incomplete tray row to pick them up.

13. The Operation of the Apparatus

As already mentioned, the central control unit (not shown) controls and coordinates the operation of each unit of the apparatus. A plurality of sensors including optical, contact and pressure sensors, provides information about ICs, their category and location, and operation of different mechanisms of the handling apparatus, the information being supplied by means of the apparatus software to the control unit.

14. The Detailed Description of the Testing Assembly 100 Operation

Referring to FIG. 1, the apparatus of the present invention operates as follows. An operator loads into the input magazine 101 a stack of uniformly oriented customer trays filled with ICs to be tested and sorted. The stack of trays is supported in the input magazine 101 by the holding means 113, 114 or 117, as best shown in FIGS. 2 and 3. When a sensor (not shown) installed in the input magazine 101 detects a tray in the magazine (or when the number of trays exceeds a predetermined number), a signal is generated permitting to start processing. If the amount of trays becomes lesser than a predetermined number, said sensor generates a warning signal to inform the operator.

The operation of the tray elevator 104 will be illustrated now referring to example embodiment presented in FIG. 2. In FIG 2b the tray elevator is shown in its lowermost position with its plate 123 taking a tray 5 from the transporter 105. Then, as shown further in FIG. 2c, the power cylinder 126 lifts the plate 123 arranged on the extendible 122 from its lowermost position to the level on which the upper surface of the tray 5 is positioned abreast the center of the cog-wheel 113. At this moment, the stopper 114 is retracted by the solenoid 115 and disengages the cog-wheel 113 which rotates loosely as the tray 5 passes upwards. When the control unit receives the information from the sensor which detects that the lowermost tray is lifted over this level, the stopper is activated again to return to its extended state and engage the cog-wheel 113 whose cogs fix the tray 5 as shown in FIG. 2d. At this point, the elevator 104 starts to move down to take the next tray to be added to the magazine.

The trays are taken from the magazine in a similar manner, i.e. the tray elevator plate reaches the level of the lowermost tray in a stack, takes it when the cog-wheel is released and lowers the tray on the level of the transporter belt while the penultimate tray takes its place on the cogs of the cogwheel 113. It shall be noted that all the elevators 104, 104′, 204, 204′, 304, 304′ of the proposed device operate in the same mode.

On the next step, the elevator drops the tray 5 onto the transporter 105 which shall be positioned by means of the stepper motor 135 so as to receive the tray exactly between the four of the fixing ribs 120. Said position of the transporter 105 shall correspond to positions of certain rows of the tray flow located in the operation planes of the manipulators 160, 160′. This may be achieved by setting the transporter 105 step to be equal to a customer tray interrow pitch, preferably to a doubled tray interrow pitch. It will also be appreciated that the elevator 104 may also be pneumatically activated, in which case its operation may differ in some details, that shall be evident for a specialist in the art and will not be discussed herein.

To provide the continuous operation of the testing assembly 100, the elevator 104 takes from the magazine 101 one tray filled with ICs to be tested after another unless the stack of trays is over or the number of trays in the stack is lesser than a predetermined critical limit or the elevator 104 operation is interlocked because of some failure in the apparatus. In its turn, the transporter 105 operated by the stepper motor 135 moves the trays stepwise from the input transfer area under the input magazine 101 into the thermostat chamber 150 in which the ICs are tested under desired temperature conditions.

In the preferred embodiment of the present invention, two manipulators 160, 160′, as shown in FIG. 5, are provided, wherein the first manipulator 160 processes ICs in even rows of the tray flow, and the second manipulator 160′ processes ICs in odd rows. Respectively, the transporter 105 step is equal generally to the two tray interrow pitches, so that the IC manipulator 160 leaves one IC row unprocessed, while this row and other even rows are processed by the second manipulator 160′. Thus, if the IC manipulator 160 starts processing from the first tray row, the next row to be processed by this manipulator is the third one.

As both IC manipulators 160, 160′ operate preferably synchronously and have similar operation cycles, operation of only one IC manipulator 160 will be explained in detail herein. The manipulator 160 operation cycle comprises generally twelve steps shown in the following diagram illustrating processing of the <<n>>-th row of the tray flow.

### Cyclic Operation of the Testing Assembly Manipulator

| step number | 1 | 2 | 3 | 4 | 5 | 6 | 7 | 8 | 9 | 10 | 11 | 12 |
|---|---|---|---|---|---|---|---|---|---|---|---|---|
| Header | OFF | OFF | OFF | OFF | OFF | ON | OFF | OFF | OFF | OFF | OFF | ON |
| Upper beam | n − 2 | n − 2 | n − 2 | N | n | n | n | n | N | n + 2 | n + 2 | n + 2 |
| Sockets | Fixed | Fixed | Open | Open | open | fixed | fixed | fixed | Open | Open | open | fixed |
| Upper bar | Out | out | In | In | out | out | out | out | In | In | out | out |
| Frame | ↑ | ↑ | ↑ | ↑ ↓ | ↓ | ↓ | ↓ | ↓ | ↓ | ↓ ↑ | ↑ | ↑ |
| Lower bar | In | Out | In | In | out | out | in | out | In | In | out | out |
| Lower beam | Empty | N | N | n − 2 | n − 2 | n − 2 | empty | n + 2 | n + 2 | N | n | n |
| Lower | OFF | ON | ON | ON | ON | OFF | OFF | ON | ON | ON | ON | OFF |
| grippers | | | | | | | | | | | | |
| Transporter | ON | OFF | OFF | ON | OFF | OFF | ON | OFF | OFF | ON | OFF | OFF |
| Row to be | N | | | n − 2 | | | n + 2 | | | N | | |
| Positioned | | | | | | | | | | | | |

At the first step the lower pneumatically activated bar 166 of the manipulator 160 frame 162 is shifted to its retracted position, while the transporter 105 positions the <<n>>-th ICs row of the tray flow in the operational plane of the manipulator 160. The upper retractable bar 166 of the frame 162 is in its extended position, while the ICs of the “n-2”th row retained by the suction grippers 161 are inserted into the sockets 183. The pneumatically activated loose cylinders 187, 187′ are in their initial intermediate position; plate 184 with the spring loaded fixtures 186 mounted therein is in its initial position; ICs pins are clamped; suction grippers 161 of the lower connecting beam of the frame are disconnected from the source of suction.

At the second step both loose cylinders 187, 187′ are activated. The rollers 189 pushed by said cylinders roll over the wedges 188 to pull the plate 184 towards the stationary plate 182. The spring-loaded socket fixtures 186 mounted therein open to release ICs pins so that the ICs can be taken out of the sockets 183. The lower connecting beam suction grippers 161 are connected to the source of suction while the pneumatically activated lower bar 166 is shifted to its extended position. When the suction grippers 161 approach the upper surfaces of the ICs of the “n”-th row in a tray, the ICs are captured by the suction grippers.

At the third step, both the upper and the lower bars 166 are shifted to their retracted position; thereby the tested ICs from the <<n-2>>th row are taken out from the sockets 183 by means of the suction grippers 161, and the ICs of the <<n>>th row are picked up from the tray by means of the lower connecting beam suction grippers 161.

At the fourth step, the frame 162 is turned by the pneumatically activated motor 65 by 180° around its axis and positioned in a generally vertical plane abutting against the stops. The inertia forces of the frame 162 on its travel near the stops are absorbed by one of the shock-absorbers 168. In the turned position the former lower connecting beam of the frame 162 becomes its upper connecting beam adjacent to the header 180, so that the ICs of the <<n>>th row taken by the suction grippers can be inserted and tested in the sockets 183 of the header 180. The former upper connecting beam, in turn, becomes the lower connecting beam whose suction grippers carry the tested ICs from the <<n-2>>th row to place them to their original positions. The transporter 105 moves the tray backwards for two interrow pitches, so that now its <<n-2>>-th row is positioned in the manipulator 160 operational plane.

At the fifth step, both pneumatically activated bars 166 are driven to their extended positions; thereby the ICs of the <<n>>-th row held by the suction grippers of the upper frame connecting beam are inserted in the open sockets 183, while the ICs of the <<n-2>>-th row held by the lower connecting beam suction grippers 161 are placed back to their original places in the tray 5.

At the sixth step, both cylinders 187 are deactivated, the rollers 189 return to their initial position, the plate 184 under the action of spring-loaded fixtures 186 returns to its initial position; thereby the ICs pins are clamped to ensure electrical contact of the ICs with the sockets 183. Then, the testing equipment is connected, and the testing begins. Simultaneously, the lower connecting beam suction grippers 161 holding the ICs of the “n-2”th tested ICs row which are now placed back in the tray are disconnected from the source of suction and connected with ambient air, thus releasing their ICs to leave them in the tray 5.

At the seventh step that is similar to the first step, the testing is over, and the testing apparatus is disconnected from the tested ICs. The lower bar 166 is driven to its retracted position in which the suction grippers 161 are lifted. Then, the transporter 105 makes two steps to move the tray flow forward for 4 interrow pitches and position the <<n2>>th tray row in the operational plane of the manipulator 160.

At the eighth step, similar to the second step, both loose cylinders 187, 187′ are activated again, so that the plate 184 is pulled toward the stationary plate 182. As a result, the fixtures 186 release the ICs pins allowing to take them out of the sockets. Simultaneously, the pneumatically activated lower bar 166 is shifted to its extended position, while the suction grippers 161 of the lower connecting beam are communicated to the source of suction. When the suction grippers 161 get into contact with the upper surfaces of the ICs in <<n+2>>-th row, a connection between them is created.

At the nineth step, similar to the third step, both bars 166 are shifted to their retracted positions; thereby the tested and attributed ICs of <<n>>-th row are captured by the grippers 161 of the upper connecting beam and taken out from the open sockets 183 of the header 180 while the ICs of the <<n+2>>-th row to be tested are picked up from the tray by the lower connecting beam suction grippers 161.

At the tenth step, similar to the fourth one, the frame 162 is turned backwards by means of the pneumatically activated motor 165. The frame 162 is turned by 180° and positioned in a generally vertical plane abutting to the stop 168. In the returned position of the frame 162 its primarily lower connecting beam again becomes the lower connecting beam with the tested and attributed <<n>>-th ICs row to be placed in its original place. The originally upper connecting beam returns to its upper position (which is adjacent to the header 180), allowing to insert the ICs of the <<n+2>> row into the sockets. The transporter 105 positions the <<n>>-th row in the manipulator 160 operational plane displacing the tray flow backward on two interrow pitches.

At the eleventh step, similar to the fifth one, both pneumatically activated bars 166 are driven to their extended positions, so that the <<n+2>>-th ICs row held by the upper frame connecting beam suction grippers 161 are inserted in the open sockets 183. Simultaneously, the <<n>>-th ICs row held by the lower connecting beam suction grippers 161 is placed on its original place in the tray 5.

At the twelfth step, similar to the sixth one, the cylinders 187, 187′ are turned to their initial position, the rollers 189 roll down from the wedges 188, releasing the plate 184 with fixtures 186 which clamp the pins, ensuring electrical contact of the <<n+2>>-th ICs row with the sockets 183. Then the testing equipment is connected, and the testing routine begins. Simultaneously, the suction grippers 161 of the lower connecting beam, the grippers holding the <<n>>-th tested ICs row placed in the tray, are isolated from the source of suction and communicated with the ambient air, so that this ICs row is disconnected from the grippers 161, and its ICs remain in their original places in the customer tray. The full cycle of the manipulator 160 operation is repeated until all the ICs are tested.

Alternatively, both manipulators 160, 160′ can process one tray row after another until the tray is completely empty, whereupon the transporter 105 will displace the tray flow forward by the distance equal to the tray width. In this case, the above detailed operation of the IC manipulator can also be applied with the difference in that the numbers of rows and pitches should be changed from <<n-2>> to <<n-1>>, and from <<n+2>> to <<n+1>>, and a step of the transporter 105 should be changed to one interrow pitch.

In an alternative embodiment of the invention in which suction grippers of both manipulators are staggered so that each manipulator can operate with incomplete row of ICs belonging to either odd or even columns of the tray flow, each row is processed successively one after another. In this case a problem of processing of ICs in customer trays in which intercolumn pitch is smaller than a minimal intersocket pitch, can be advantageously solved.

It shall be appreciated that the operation of other alternative embodiments of the IC manipulator can be adjusted respectively with regard to its modification by a specialist in the art. Thus, the number of testing assemblies can be increased if desired, for example, to process IC at different temperatures, one testing assembly can be arranged in a thermostat chamber held under negative temperature, the next one can be at an ambient temperature, and the third, at an elevated temperature.

After processing in manipulators 160, 161, the IC tray flow is moved out of the said chamber through the output port. Then, each tray with the tested ICs is transferred by the transporter 105 to the transfer area of the output magazine 102, where it is processed similarly by the elevator 104′ and positioned in the output tray magazine 102. It shall be mentioned that the elevator operates during the transporter operation cycle stop to avoid interlocking the transporter operation.

Alternatively, the transporter 105 may be linked with the transporter 205 by the auxiliary toothed belts 229, thereby during the testing assembly 100 operation the tray flow is directed automatically onto the transporter 205 and then the trays are lifted one by one by the elevator 204 and stored in the sorting assembly input magazine 201. It will be appreciated in this case the both transporters 105 and 205 move synchronously in one direction.

Another alternative is the automatic transfer of the stack of trays filled with the tested ICs into the sorting assembly input magazine 201 when the testing assembly 100 operation is over. In this case, trays from the stack can be lowered one after another by the elevator 104, transported to the sorting assembly 200 transfer area and lifted by the elevator 204 to the magazine 201.

While moved by the transporter 105, the tray is generally held by two fixing ribs 120 at the front and two fixing ribs 120 from behind. When the rear fixing ribs 120 at the rounded output end of the rectilinear portion of the toothed belts 130 come out of the contact with the tray, two auxiliary fixing ribs 120 of the auxiliary toothed belts 229 push the tray from behind to avoid the tray sliding over the belt and losing its precise position on his way from one transporter to another until respective fixing ribs 220 appear and get into contact with the tray.

15. The Detailed Description of the Sorting Assembly 200 Operation

The operation of the sorting assembly 200 will further be described in detail referring to FIGS. 1, 8 and 9. The trays of a tray flow are transported via elevators 204, 204′ and the transporter 205 from one magazine (which is in this case the input magazine, e.g. magazine 201) to another (in this case, the output magazine, e.g. magazine 202), while the manipulator 260 selects from the tray flow the ICs of the current quality category and send these ICs to the packing assembly 300 via the gravity rail 280. When the current quality category is over, the tray flow is reversed, so that the sorting assembly 200 will extract the ICs of the next quality category, while both magazines 201 and 202 operate alternately. This will repear until all the quality categories are extracted and sent to the packing assembly. Preferably, the operation of the sorting assembly 200 starts when the input magazine 201 is filled with trays filled with the tested and attributed ICs to be sorted, and the input magazine 202 is empty. When a row of IC containing at least one IC of a desired quality category is positioned in the operational plane of the manipulator 260, the respective suction gripper(s) 261 of the lower retractable bar 266 is(are) selectively connected to the negative pressure source, and this retractable bar 266 shifts to its extended position. (It shall be mentioned that if no IC of the current quality category is found in a given row, the transporter 205 moves the tray flow until a row with at least one desired IC is positioned in the operational plane of the manipulator 260. The operation of the IC manipulator can be interrupted for lifting and lowering operations of elevators 204, 204′). Those suction grippers which are connected to the source of suction, when brought into contact with the Ics, pick up the desired ICs, while the ICs of other quality categories remain in their places. The retractable bar carrying the ICs, shifts to its retracted state, and the rotary frame 262 is turned to its upper position which is close to the gravity rail.

The motor 283 opens the gravity rail input flaps 282 by means of respective levers and rods. Then the pneumatically activated bars 266 are driven to their extended position, so that the selected ICs carried by the upper suction grippers 161 are inserted into the rail 280. At this time the suction grippers 262 on the lower retractable bar come into contact with the ICs of the next row of the tray flow, and the next desired ICs are picked up by the respective suction grippers 261.

The motor 283 closes the input flaps with ICs inside the rail 280, and the suction grippers are disconnected from the negative pressure source; thereby the ICs inside are released, and slide down the rail through the singularizing means 284 into the packing assembly 300. When the ICs of the current quality category are sorted and picked up, the transporter 205 and the elevators 204, 204′ start to transfer the tray flow in a reverse order until at least one IC of the next quality category is positioned in the operational plane of the manipulator 260, whereupon the manipulator starts to select the ICs of the next quality category. The unit operates in continuous mode until all the trays are empty and collected in one of the magazines 201 or 202. It shall be understood that every tested IC is attributed to a certain group on the basis of test results stored in the testing apparatus or a controlling computer, while the number of quality categories is unlimited.

16. The Operation of the Gravity Rail 280

As already mentioned above, the gravity rail 280 is a component part of both the sorting assembly 200 and the packing assembly 300, and therefore it operates in conjunction with both these assemblies.

The operation of the driving means 283, 289 for opening and closing the pivotally mounted input 282 and output 288 flaps can be effected by an electrical motor, pneumatically activated motor or a solenoid arranged on the bar 281 and provided with respective mechanical linkage (such as levers and rods) to said flaps. These mechanisms are well known in the art; therefore their operation will not be discussed herein.

Referring now to FIGS. 11(a-d), the operation of the gravity rail in conjunction with the operation of the sorting and packing assemblies will be explained in more detail.

The upper part of the rail 280 cooperates with the sorting assembly 200. To provide the possibility of inserting the IC picked up by the IC manipulator 260, the driving motor 283 of the gravity rail 280 opens the input flaps 282 by means of respective levers and rods. After the pneumatically activated bars 266 are driven to their extended position, and the selected ICs carried by the upper suction grippers 161 are inserted into the rail 280, the flaps 282 are shifted to their closed position to form a sliding surface for the ICs which are loosely transported downwards into the packing assembly.

On their way down the ICs pass the singularizing means 284 for providing a predetermined distance between the neighbouring ICs sliding down to the output area of the rail. The singularizing means 284 comprises two stoppers 285, 286, each stopper being formed of a spring-loaded tab 292, 294 for holding the ICs, and a solenoid for activating the tab, the lower stopper tab 294 having a notch for blocking the rail 280 internal path in de-energised state. The upper stopper tab 292 does not have a notch, and in de-energised state simply presses an IC against the inner surface of the rail to prevent it from sliding down.

If a sensing system detects that the distance between the neighbouring ICs sliding down the rail is more or less than a predetermined delay period, the stopper 284 is activated.

The stopper operates as follows. A first IC of a row of the ICs sliding down the rail is stopped by the lower stopper tab 294, the second IC rests upon the first IC and so on, until the whole row is stopped. At the same time, as soon as the first IC is detected by a sensor, a signal is generated to activate the upper stopper 285 whose spring-loaded tab 292 presses the second IC against the rail and holds it. When the second IC is latched, the lower stopper 286 is activated, the tab 294 is retracted, unblocking the IC path and releases the first IC to slide down to the output area.

After that, the stopper 286 is de-energised to block the path, while the stopper 285 is energized for a time which is enough for the next IC (which was the second one) to be released by the upper stopper tab 292 to pass and slide down to the lower stopper 286 whose tab 294 stops the IC detected by the sensor. The cycle is repeated as described above until the whole row of ICs is over.

It will be appreciated that the operation of the singularizing means 284 may be interrupted when the previously positioned ICs are still in the output area or when the output flaps 288 are open. The time interval or the space between the ICs passing the singularizing means 284 is controlled by the rate of the singularizing means 284 activation or, in other words, by the frequency of controlling impulses.

When the IC flow (in which the ICs are spaced as described above) enters the output area of the rail 280, the solenoid-activated positioning stoppers 287 arranged in series with a pitch which is essentially equal to the column pitch of the customer tray, are activated, so that their tabs do not block the IC path (in their de-energised state the path is blocked). When the first IC reaches the mechanical stop at the very bottom of the rail 280, the IC is detected by a respective sensor, which generates a signal to de-energize the lowest solenoid activated stopper 287 (actually the second place to position an IC) which stops the IC by pressing it with the tab to the closed rail flaps 288. The presence of the second IC positioned in the output area is detected by the respective sensor which signals to activate the second solenoid activated stopper to receive the third IC and so on. Thus, the positioning stoppers 287 are activated one after another until all the available positions are occupied by the ICs fixed in predetermined positions by respective stopper's tags.

If the number of the ICs positioned in the output area of the rail 280 is not sufficient to fill a row in a tray, the operation of the IC manipulator 360 will be interlocked by the controlling computer until a new portion of sorted ICs is added into the rail 280 by the IC manipulator 260. An incomplete row of sorted ICs can be received by the manipulator only in case when these ICs are the last in the current quality category. To receive an incomplete row of IC, at least one connecting beam of the manipulator 360 shall be provided by selectively controlled suction grippers.

17. The Detailed Description of the Packing Assembly 300

The packing assembly 300 receives the ICs from the gravity rail 280 and places them in a tray, e.g. a customer tray.

In the preferred embodiment, the operation of the packing assembly 300 starts when the input magazine 301 is filled with a stack of empty customer trays which are preferably the same as the trays at the input of the handling apparatus and the same as used in the test 100 and sort 200 assemblies. However, the packing assembly can also be used to pack the ICs in any other type of trays, for example, in non-standard trays, wherefore the distance between the suction grippers may be adjusted as well as other parameters, so as to adapt the process of packing for the desired type of the tray accordingly.

Generally, the input magazine 301 can be arranged at the either end of the transporter 305, the other end being provided for the output magazine. The packing assembly elevators and the transporter 305 operate similar to the sorting assembly elevators and the transporter 205 transferring a tray flow from the input magazine 301 to the output magazine 302 while the manipulator 360 packs one current quality category of ICs after another onto the customer trays. Preferably, when a certain quality category is over and the current tray is not filled yet, the packing of the next group starts with an empty tray, in other words, the ICs of different quality categories do not meet on one tray. The operation of the packing assembly 300 continues until all the ICs under processing are packed in the customer trays and stored in the output magazine 302. Finally the stack of trays with sorted ICs thereon is unloaded by an operator.

The IC manipulator 360 operation cycles are similar to the operation of the testing assembly and sorting assembly, and can easily be compiled by a specialist in the art as shown below.

### Cyclic Operation of Sorting Assembly

| Step number | 1 | 2 | 3 | 4 | 5 | 6 | 7 | 8 | 9 | 10 |
|---|---|---|---|---|---|---|---|---|---|---|
| Output flaps | Closed | closed | closed | Open | Open | Closed | closed | closed | Open | Open |
| Upper grippers | ON | OFF | ON | ON | ON | ON | OFF | ON | ON | ON |
| Upper | n − 1 | Empty | n | N | N | N | empty | n + 1 | n + 1 | n + 1 |
| connecting | | | | | | | | | | |
| beam | | | | | | | | | | |
| Upper bar | IN | IN | OUT | OUT | IN | IN | IN | OUT | OUT | IN |
| Frame | ↑ | ↑ ↓ | ↓ | ↓ | ↓ | ↓ | ↓ ↑ | ↑ | ↑ | ↑ |
| Lower bar | IN | IN | OUT | OUT | IN | IN | IN | OUT | OUT | IN |
| Lower | Empty | n − 1 | n − 1 | empty | empty | Empty | n | n | Empty | empty |
| connecting | | | | | | | | | | |
| beam | | | | | | | | | | |
| Lower grippers | OFF | ON | ON | OFF | OFF | OFF | ON | ON | OFF | OFF |
| Transporter | OFF | ON | OFF | OFF | OFF | OFF | ON | OFF | OFF | OFF |
| Row positioned | | n − 1 | | | | | n | | | |

18. The Operation of the Filters 40, 50.

The tilters 40, 50 can be installed optionally, and are operable to take out automatically empty trays from the sorting assembly and pass them to the packing assembly 300. The tilters 40, 50 operate as shown in FIGS. 12a-12b.

When an empty tray passes beyond the second magazine 202, and is positioned in the tilting area over the plate 41, the tilter 40 starts. The pneumatically activated power cylinder 45 pivotally turns by the angle of 35° the lever 43 and its main arm 42 with a plate 41 thereon. The empty tray is raised by the plate 41 from the transporter 205, and tilted with said plate being stopped from sliding thereon by the solenoid activated stopper 44. Simultaneously, the tilter 50 is placed by means of the pneumatic activated power cylinder 55 in its receiving position inclined at the angle 35° while the plate 51 passes through the opening between double belt 330.

When the tilters 40, 50 form thereby a common plane for the tray to slide down, the stopper 44 is activated to release said tray which slides down to the stop 54. After that the upper tilter 40 returns in its initial position.

The lower tilter 50 is returned to its initial position, while the plate 51 is lowered thereby the transferred tray is positioned on the belt 330.

19. An Alternative Embodiment of the Invention

A series arrangement of both manipulators 160, 160′ allows to process ICs in customer trays in which an ICs column pitch is lesser than a minimal possible test socket pitch on the testing apparatus header 180. The alternative embodiment of the present invention has generally similar design with the preferred embodiment but differs in suction grippers and test sockets arrangement described hereinafter. Thus, the suction grippers of two manipulators may be staggered so that each manipulator can successively process incomplete rows of ICs. In this case the number of suction grippers in each manipulator frame is reduced to the number of ICs in an incomplete row. The staggered suction grippers are spaced along bars with a pitch which is generally equal to a doubled intercolumn pitch so that said grippers are aligned with ICs of the respective incomplete tray row. It is clear that the correspondent or different changes can be made to the other manipulators of the handler.

In the alternative embodiment of the invention the header has a correspondingly reduced number of test sockets. Two rows of sockets are staggered to be aligned with respective rows of the upper bar suction grippers.

It shall be understood that the operation of the present handler is controlled and directed by the computer control system operated according to a computer program product. In particular, the mechanical movements of the various devices and mechanisms of the handler, including the tray magazines, elevators, transporters, and IC manipulators, are directed by this software utilized by the control system. Once these features of the present invention are understood, the writing of this software is within the abilities of one of ordinary skill in the art. Furthermore, the mechanical movements of the various mechanisms and devices can be actuated pneumatically, electrically or by other means, as is apparent to one skilled in the art. All paths of the IC are monitored during the operation of the handler and each IC is traced starting from unloading a cassette at the loading means and up to the discharge of the IC in the discharge means.

Each system module is completely self-contained, allowing common modules to be assembled, checked out and calibrated without regard for the specific system in which it will be used. This approach reduces the module cost and allows users to replace the defective modules quickly without further set-up, adjustment or calibration.

The possibility of using standard common devices and modules minimize the expense of custom-modified systems to meet specific customer requirements. The modular design approach simplifies the maintenance of the handler. The defective modules may be “repaired by replacement”, thus reducing system downtime and minimizing maintenance personnel requirements.

It shall also be appreciated that the above are example embodiments only and that various modifications may be made to the embodiments described above within the scope of the present invention.

We claim:

1. A handling assembly for handling integrated circuits and trays for receiving these integrated circuits, the handling assembly comprising:
at least one integrated circuit manipulator having a holder pivoted on a fixed axis of rotation; the holder having a plurality of grippers arranged substantially in the plane passing through said axis of rotation, the holder being adapted to rotate said plurality of grippers at least to a first and second angular positions,
a tray transporter adapted to move a tray into an operational position in which at least one of the integrated circuits in the tray is engageable by at least one of the grippers rotated to the first angular position, and
an integrated circuit receiving/releasing means engageable by at least one of the grippers rotated to the second angular position.

2. The handling assembly of claim 1, further comprising at least one tray magazine for stacking the trays, wherein the magazine is provided with a mechanism for moving the trays between the stack and the tray transporter.

3. The handling assembly of claim 1, wherein said tray magazine is arranged upstream the operational position to function as an input tray magazine, the handling assembly further comprising another tray magazine arranged downstream the operational position to function as an output tray magazine.

4. The handling assembly of claim 1, wherein the grippers are provided with extension means for extending each gripper from and retracting it to the holder.

5. The handling assembly of claim 1, wherein the holder comprises a rectangular frame having two spaced pivoted beams pivoted centrally on the axis of rotation and respectively interconnected by two parallel connecting beams, wherein grippers of said plurality of grippers are respectively mounted on each of said two parallel beams, and wherein the holder and tray transporter are arranged in such a way that, when this tray is in the operational position, at least some of the integrated circuits in a tray are engageable by grippers of said plurality of grippers rotated to the first angular position.

6. The handling assembly of claim 1, wherein the holder comprises an oblique-angled frame having two spaced pivoted beams pivoted centrally on the axis of rotation and respectively interconnected by two tapering connecting beams, wherein grippers of said plurality of grippers are respectively mounted on each of said two tapering beams, and wherein the holder and tray transporter are arranged in such a way that, when this tray is in the operational position, at least some of the integrated circuits in a tray are engageable by grippers of said plurality of grippers rotated to the first angular position.

7. The handling assembly of claim 1, further comprising another integrated circuit manipulator, both integrated circuit manipulators being arranged in series.

8. The handling assembly of claim 7, wherein said receiving/releasing means are constituted by test sockets of a testing apparatus, wherein the sockets are spaced in correspondence with the grippers.

9. The handling assembly of claim 1, wherein said receiving/releasing means comprises an inclined rail means.

10. A handling apparatus for handling integrated circuits and trays for receiving thereof, the apparatus comprising a first handling assembly, a second handling assembly and inclined rail means common for both handling assemblies, so that the handled integrated circuits can slide down along the rail means from the first handling assembly located upstream to the second handling assembly located downstream, wherein each of the first and the second handling assemblies comprises the handling assembly for handling integrated circuits and trays for receiving these integrated circuits, the handling assembly comprising:
at least one integrated circuit manipulator having a holder pivoted on a fixed axis of rotation; the holder having a plurality of grippers arranged substantially in the plane passing through said axis of rotation, the holder being adapted to rotate said plurality of grippers at least to a first and second angular positions,
a tray transporter adapted to move a tray into an operational position in which at least one of the integrated circuits in the tray is engageable by at least one of the grippers rotated to the first angular position, and
an integrated circuit receiving/releasing means engageable by at least one of the grippers rotated to the second angular position.

11. A handling apparatus as claimed in claim 10, further comprising a third handling assembly disposed upstream of the first handling assembly, wherein the third handling assembly further comprising another integrated circuit manipulator, both integrated circuit manipulators being arranged in series, while the tray transporters of the first handling assembly and the third handling assembly are joined together.
